(19) United States
(12) Patent Application Publication
(10) Pub. No.: US 2012/0097092 A1
(43) Pub. Date: Apr. 26, 2012

(54) APPARATUS FOR GROWING SINGLE CRYSTALS

(76) Inventor: Meng Zhu, Oakland, CA (US)

(21) Appl. No.: 12/908,157

(22) Filed: Oct. 20, 2010

(51) Int. Cl. C30B 19/08

(52) U.S. Cl. 117/60; 117/206; 117/54; 117/61

(57) ABSTRACT

A crystal growth apparatus includes a vacuum sealable container, a crucible in the vacuum sealable container. The crucible can receive a polycrystalline material. The crucible comprises a seed well configured to hold a seed crystal. The wall of the crucible can include a base layer of a first material and a coated layer of a second material. The base layer provides mechanical strength to the crucible. A heater can heat the polycrystalline material to form a melt in contact with the seed crystal. The coated layer of the crucible allows a single crystal to grow in the melt.

### BACKGROUND OF THE INVENTION

The present invention relates to technologies for growing single crystals of Group III-V, Group II-VI, Group IV materials.

Electronic devices require large and uniform single semiconductor crystals that can be sliced and polished to provide substrates for integrated circuits. For example, power amplifiers in mobile phones and other communication devices are fabricated on GaAs substrates.

Typical industrial manufacture methods of GaAs crystals include the pulling method, the horizontal boat method, the horizontal gradient freeze method, the vertical boat method, and the vertical gradient freeze method. In a crystal growth process, a raw polycrystalline material is heated to above its melting point. The melt is brought into contact with a seed crystal, allowing the melt to crystallize from the seed crystal. An exemplified commercial crystal growth system 100, shown in FIG. 1, includes a sealable ampoule 110 that provides vacuum for crystal growth, a crucible 120, and heaters (not shown) around the ampoule 110 for melting a raw polycrystalline material placed in the crucible 120 to form a material melt 130. The sealable ampoule 110 is typically made of quartz. The crucible 120 has a seed well 140 in the lower portion. The crucible 120 is typically made of pyrolytic boron nitride (pBN), which assists growth of a single crystal from the seed crystal.

A drawback for some conventional crystal growth systems is that they comprise specialized materials such as pBN, which is expensive to construct and costly to replace. It is thus desirable to lower the costs of the components in the crystal growth system. Another need for crystal growth is to simplify the number of components as well as the number of steps in growing crystals.

### SUMMARY OF THE INVENTION

The presently disclosed crystal growth apparatus uses a crucible made of a base layer coated by a layer of crystal-assisting material, which assures growth of single crystals as well as reducing the amount of crystal-assisting material used comparing to some conventional crystal growth systems.

The presently disclosed crystal growth apparatus can simplify the process and reduce the number of materials fed in the crystal growth of III-V Group and II-VI Group materials.

In a general aspect, the present invention relates to a crystal growth apparatus that includes a vacuum sealable container; a crucible in the vacuum sealable container, wherein the crucible can receive a polycrystalline material, wherein the crucible comprises a seed well configured to hold a seed crystal, wherein the walls of the crucible comprise a base layer of a first material and a coated layer of a second material on at least a portion of an inner surface of the base layer, wherein the base layer provides mechanical strength to the crucible; and a heater that can heat the polycrystalline material to form a melt in contact with the seed crystal, wherein the coated layer of the crucible allows a single crystal to grow in the melt.

Implementations of the system may include one or more of the following. The seed well can be at the lower portion of the crucible, wherein the crucible is configured to allow the single crystal to grow vertically. The crucible can have the shape of a horizontal boat, wherein the seed well can be at one side of the crucible. The second material in the coated layer can include pyrolytic boron nitride. A portion of the inner surface of the base layer can be not covered by the coated layer. The coated layer can cover a portion of the inner surface of the base layer to prevent the single crystal to be in contact with the base layer. The coated layer can have a thickness from about 1 micron to about 100 micron. The coated layer can have a thickness from about 5 micron to about 50 micron. The first material in the base layer can include graphite. The first material in the base layer can include pyrolytic graphite. The polycrystalline material can include a Group III-V material, a Group II-VI material, or a Group IV material. The polycrystalline material can include GaAs, AlAs, GaN, CdTe, InAs, GaSb, Si, or Ge.

In another general aspect, the present invention relates to a crystal growth apparatus, that includes a vacuum sealable container; a crucible in the vacuum sealable container, wherein the crucible is configured to receive a polycrystalline material, wherein the crucible comprises a seed well configured to hold a seed crystal, wherein the walls of the crucible comprise a base layer of a first material which provides mechanical strength to the crucible; a first coated layer of a second material on at least a portion of an inner surface of the base layer; and a second coated layer on at least a portion of an outer surface of the base layer; and a heater configured to heat the polycrystalline material to form a melt in contact with the seed crystal, wherein the first coated layer of the crucible allows a single crystal to grow in the melt.

In another general aspect, the present invention relates to a method of growing single crystals which includes introducing a polycrystalline material into a crucible comprising walls having a base layer and a coated layer on at least a portion of an inner surface of the base layer, wherein the polycrystalline material can include a Group III-V material, a Group II-VI material, or a Group IV material, wherein the base layer provides mechanical strength to the crucible, wherein the coated layer can have a thickness from about 1 micron to about 100 micron; sealing the crucible is in vacuum in a container; heating the polycrystalline material to form a melt in contact with a seed crystal in a seed well in the crucible; and growing a single crystal from the melt, wherein single crystal is in contact with the seed crystal and the coated layer.

### BRIEF DESCRIPTION OF THE DRAWINGS

The following drawings, which are incorporated in and from a part of the specification, illustrate embodiments of the present specification and, together with the description, serve to explain the principles of the specification.

FIG. 1 is a schematic diagram for a conventional crystal growth system.

FIG. 2 is a front cross-sectional view of an improved crystal growth apparatus in accordance with the present invention.

FIG. 3A is a detailed front cross-sectional view of the crucible compatible with the improved crystal growth apparatus of FIG. 2.

FIG. 3B is a top view of the crucible in the improved crystal growth apparatus of FIG. 2.

FIG. 4A is a detailed front cross-sectional view of another crucible compatible with in the improved crystal growth apparatus of FIG. 2. FIG. 4B is a detailed front cross-sectional view of still another crucible compatible with in the improved crystal growth apparatus of FIG. 2.

FIG. 5 is a side cross-sectional view of another improved crystal growth apparatus in accordance with the present invention.

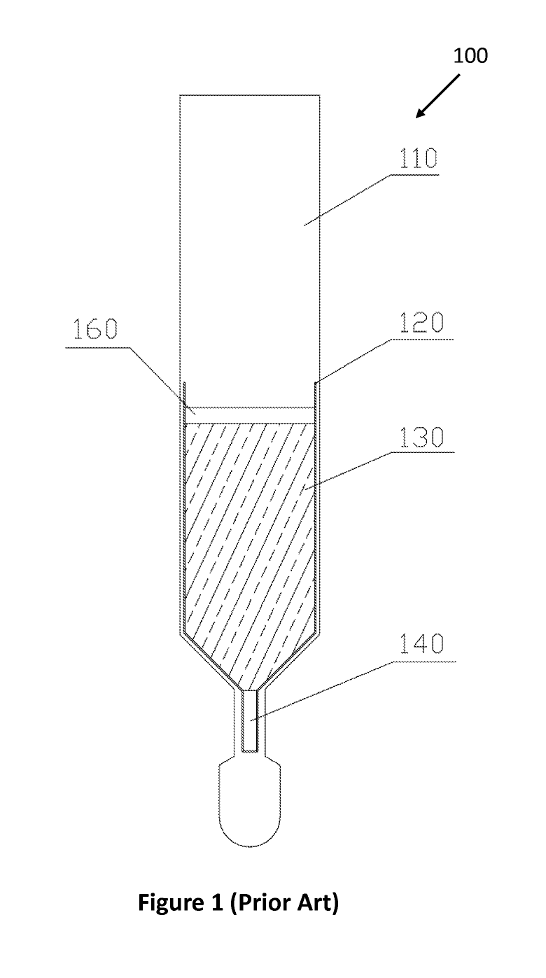

### DETAILED DESCRIPTION

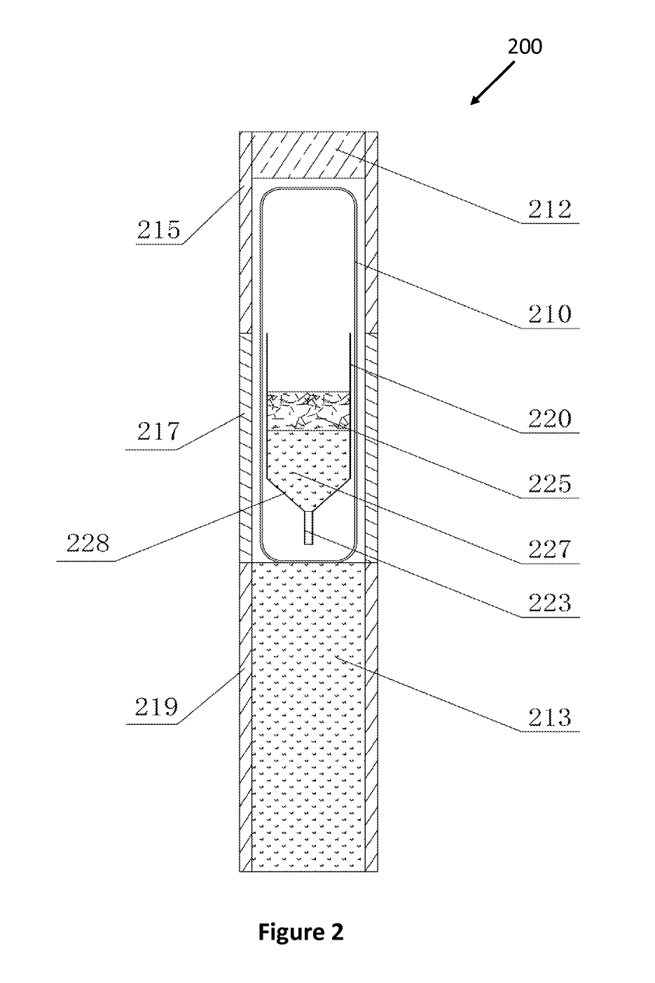

Referring to FIG. 2, an improved crystal growth apparatus 200 includes a vacuum sealable ampoule 210 and a crucible 220 inside the ampoule 210. The ampoule 210 can be made of quartz. The ampoule 210 is enclosed by an insulating material 212 on the top, an insulating material 213 at the bottom, an upper heating zone 215, a middle heating zone 217, and a lower heating zone 219. The crucible 220 can receive a raw material. For example, if a GaAs single crystal is to be formed, the raw material can include polycrystalline GaAs. The upper heating zone 215, the middle heating zone 217, and the lower heating zone 219 (which together can be referred to as “furnace”) include heaters that can heat and melt the raw material to form a melt material 225. The lower portion of the crucible 220 includes a tapered portion 228 and a seed well 223 that can hold a high quality seed crystal which provides the initial crystal surface from which the single crystal 227 can grow vertically out of the melt material 225.

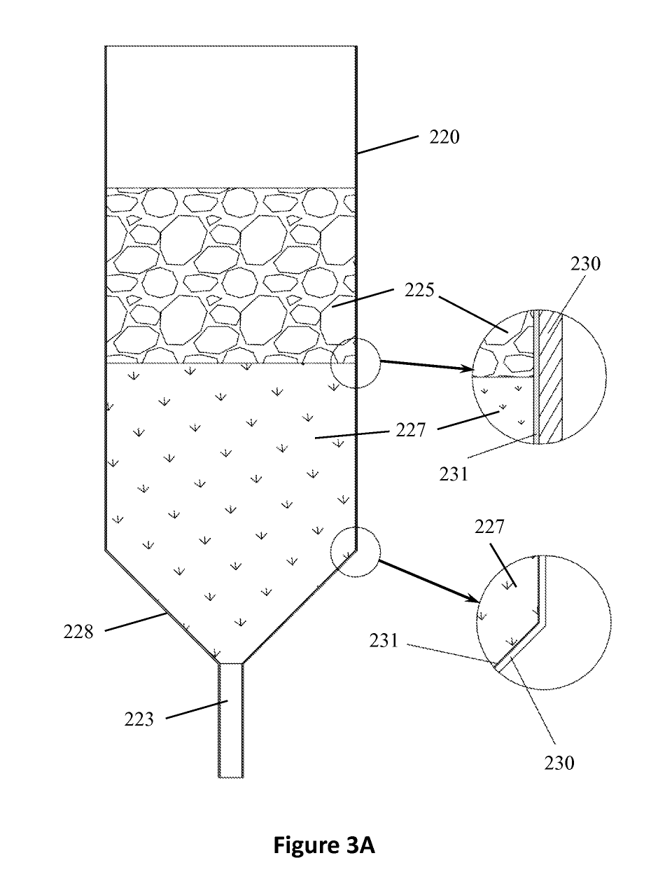

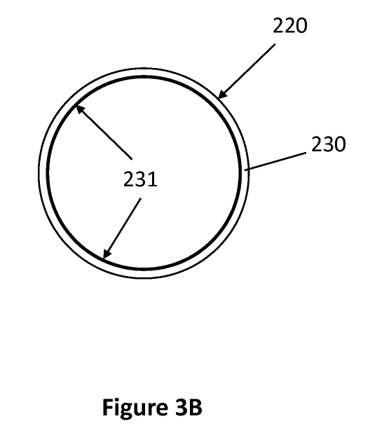

Referring to FIGS. 3A and 3B, the wall of the crucible 220 comprises a base layer 230 and a coated layer 231 coated on the inner surface of the base layer 230. The base layer 230 provides the mechanical strength required to hold the melt material and the single crystal grown from the seed crystal out of the melt material. The crucible 220 can be supported by one or more support components (not shown) from underneath. In operation, the coated layer 231 is in contact with the single crystal 227 and assists the growth of the single crystal 227. For example, for growing GaAs single crystal, the coated layer 231 can be made of pyrolytic boron nitride (pBN) which assures the growth of mono GaAs crystals without introducing defects.

An advantage of the presently disclosed improved crystal growth apparatus is that the coated layer is much thinner than the base layer. A much smaller amount of the coated material (e.g. pBN) is used in the crystal growth apparatus 200 comparing to some conventional systems (such as crystal growth system 100) in which the crucibles are formed by pBN (the material used in the coated layer in the presently disclosed apparatus). The base layer can be formed by a material much lower cost than the coated material such as graphite or pyrolytic graphite, which is at about one third or lower cost than pyrolytic boron nitride. The base layer 230 can have a thickness in the range between about 200 microns and about 600 microns. The coated layer 231 can have a thickness from about 1 micron to about 100 microns. In another example, the coated layer 231 can have a thickness from about 5 micron to about 50 micron. The thickness of the coated layer 231 can be selected based on the roughness of the base layer 230 such that the coated layer 231 can cover the surface of the base layer 230. Optionally, the coated material can also be formed on the outside surface of the crucible 220.

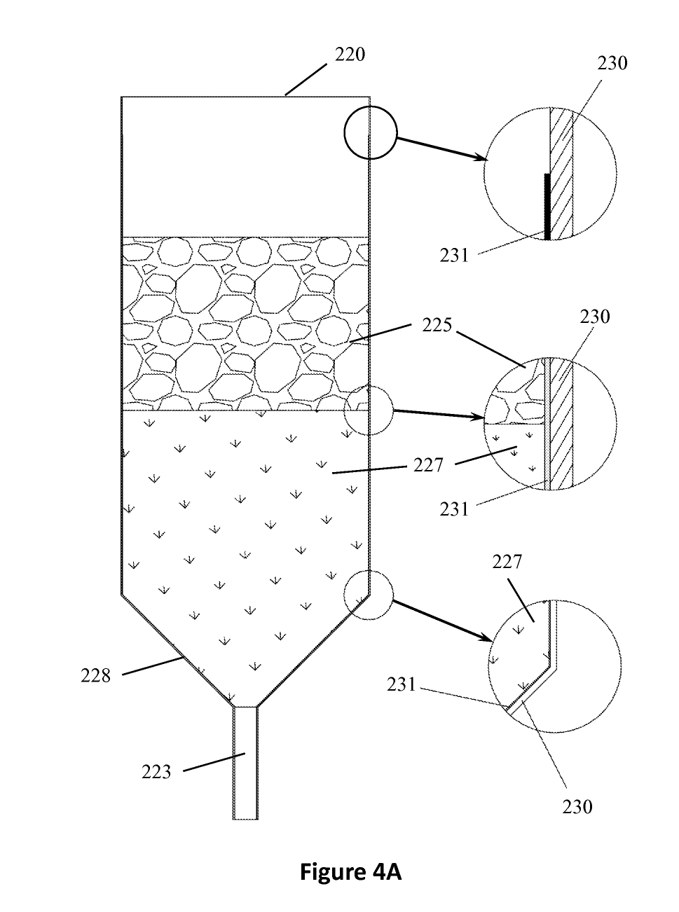

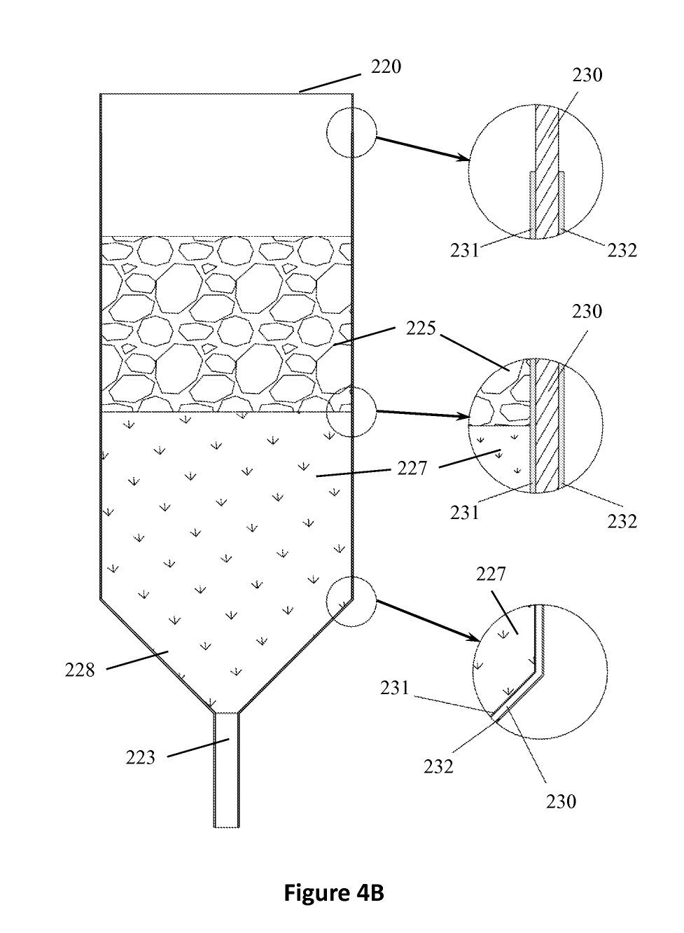

The coated layer can have different coverage on the inner surface as well as the outer surface on the wall of the crucible. Referring to FIG. 4A, the coated layer 231 can cover a portion of the inner surface of the base layer 230. The coated layer 231 is coated on at least the portion of the crucible wall that is in contact with the melt material 225 and the single crystal 227. The less coverage of the coated layer on the inner surface of the base layer can further decrease the material usage for the coated layer 231.

In some embodiments, both the inner surface and the outer surface of the base layer can be coated, which can make the crucible easier to construct. Referring to FIG. 4B, the inner surface of the base layer 230 is partially coated by the coated layer 231. Moreover, the outer surface of the base layer 230 is partially coated by a coated layer 232. The coated layers 231 and 232 can be made of the same material such as pyrolytic boron nitride.

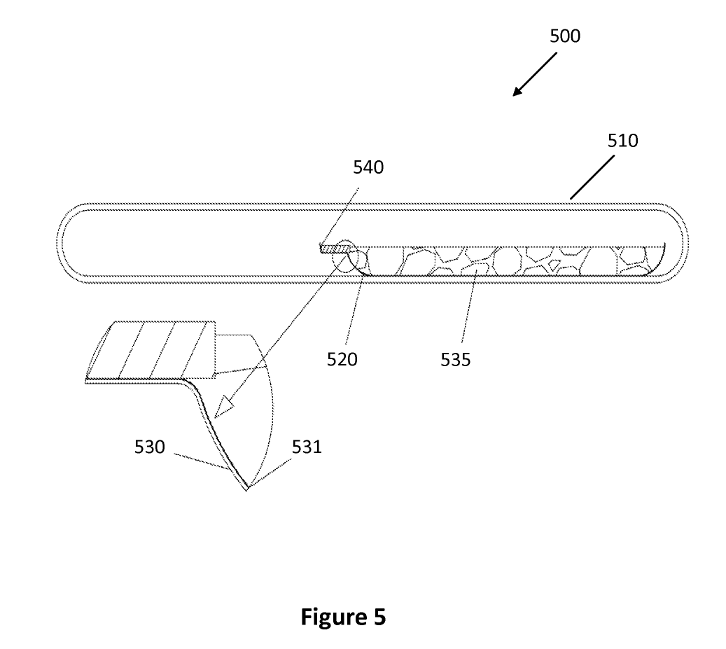

In some embodiments, referring to FIG. 5, another improved crystal growth apparatus 500 includes a vacuum sealable ampoule 510 and a crucible 520 inside the ampoule 510, which can be made of quartz. The ampoule 510 is enclosed by heaters (not shown) and insulating materials (not shown). The crucible 520 can receive a raw material 535. For example, if a GaAs single crystal is to be formed, the raw material can include polycrystalline GaAs, or gallium and arsenic materials. The heaters can heat and melt the raw material 535 to form a melt material (not shown). One end of the crucible 520 can hold a high quality seed crystal 540 which provides the initial crystal surface from which a single crystal (not shown) can grow horizontally out of the melt material. Similar to the crucible 220 in the crystal growth apparatus 200 as shown in FIGS. 2-4B, the crucible 520 includes a base layer 530 and a coated layer 531. The coated layer 530 can assist the growth of single crystals in the crucible 520. The base layer 530 can provide mechanical strength. For example, the coated layer 531 can be formed by pyrolytic boron nitride. The base layer 530 can be made of graphite or pyrolytic graphite.

It is understood the disclosed crystal growth system can be compatible with other variations without deviating from the spirit of the present invention. For example, other configurations of crystal growth can be compatible with the disclosed crucibles. Additionally, the types of materials that can be grown in the presently disclosed apparatus are not limited to the examples given above. Suitable materials can include semiconductor materials. Suitable materials can include GaAs, AlAs, GaN, CdTe, InAs, GaSb, Si, Ge, and other Group III-V, Group II-VI, Group IV materials. Moreover, the single crystals can incorporate different types of dopants, such as silicon, carbon, germanium, etc., during the crystal growth in the presently disclosed crystal growth apparatus.

What is claimed is:

1. A crystal growth apparatus, comprising:
a vacuum sealable container;
a crucible in the vacuum sealable container, wherein the crucible is configured to receive a polycrystalline material, wherein the crucible comprises a seed well configured to hold a seed crystal, wherein the walls of the crucible comprise a base layer of a first material and a coated layer of a second material on at least a portion of an inner surface of the base layer, wherein the base layer provides mechanical strength to the crucible; and
a heater configured to heat the polycrystalline material to form a melt in contact with the seed crystal, wherein the coated layer of the crucible allows a single crystal to grow in the melt.

2. The crystal growth apparatus of claim 1, wherein the second material in the coated layer comprises pyrolytic boron nitride.

3. The crystal growth apparatus of claim 1, wherein a portion of the inner surface of the base layer is not covered by the coated layer.

4. The crystal growth apparatus of claim 3, wherein the coated layer covers a portion of the inner surface of the base layer to prevent the single crystal to be in contact with the base layer.

5. The crystal growth apparatus of claim 1, wherein the coated layer has a thickness from about 1 micron to about 100 micron.

6. The crystal growth apparatus of claim 5, wherein the coated layer has a thickness from about 5 micron to about 50 micron.

7. The crystal growth apparatus of claim 1, wherein the first material in the base layer comprises graphite.

8. The crystal growth apparatus of claim 7, wherein the first material in the base layer comprises pyrolytic graphite.

9. The crystal growth apparatus of claim 1, wherein the polycrystalline material comprises a Group III-V material, a Group II-VI material, or a Group IV material.

10. The crystal growth apparatus of claim 9, wherein the polycrystalline material comprises GaAs, AlAs, GaN, CdTe, InAs, GaSb, Si, or Ge.

11. The crystal growth apparatus of claim 1, wherein the seed well is at the lower portion of the crucible, wherein the crucible is configured to allow the single crystal to grow vertically.

12. The crystal growth apparatus of claim 1, wherein the crucible has the shape of a horizontal boat, wherein the seed well is at one side of the crucible.

13. A crystal growth apparatus, comprising:
a vacuum sealable container;
a crucible in the vacuum sealable container, wherein the crucible is configured to receive a polycrystalline material, wherein the crucible comprises a seed well configured to hold a seed crystal, wherein the walls of the crucible comprise:
a base layer of a first material which provides mechanical strength to the crucible;
a first coated layer of a second material on at least a portion of an inner surface of the base layer; and
a second coated layer on at least a portion of an outer surface of the base layer; and
a heater configured to heat the polycrystalline material to form a melt in contact with the seed crystal, wherein the first coated layer of the crucible allows a single crystal to grow in the melt.

14. The crystal growth apparatus of claim 13, wherein the first coated layer has a thickness from about 1 micron to about 100 micron.

15. The crystal growth apparatus of claim 13, wherein the base layer comprises graphite, wherein the first coated layer comprises pyrolytic boron nitride.

16. A method of growing single crystals, comprising:
introducing a polycrystalline material into a crucible which comprises walls having a base layer and a coated layer on at least a portion of an inner surface of the base layer, wherein the polycrystalline material comprises a Group III-V material, a Group II-VI material, or a Group IV material, wherein the base layer provides mechanical strength to the crucible, wherein the coated layer has a thickness from about 1 micron to about 100 micron;
sealing the crucible is in vacuum in a container;
heating the polycrystalline material to form a melt in contact with a seed crystal in a seed well in the crucible; and
growing a single crystal from the melt, wherein single crystal is in contact with the seed crystal and the coated layer.

17. The method of claim 16, wherein the coated layer comprises pyrolytic boron nitride.

18. The method of claim 16, wherein the base layer comprises graphite.

19. The method of claim 16, wherein the single crystal is grown vertically from above the seed crystal in the crucible.

20. The method of claim 16, wherein the single crystal is grown horizontally from the side of the seed crystal in the crucible.
